(19) United States
(12) Patent Application Publication
(10) Pub. No.: US 2013/0221537 A1
(43) Pub. Date: Aug. 29, 2013

(54) SEMICONDUCTOR DEVICE AND ELECTRONIC APPARATUS

(71) Applicant: Huawei Technologies Co., Ltd., (US)

(72) Inventors: HuiLi Fu, Shenzhen (CN); Ting Lei, Shenzhen (CN); Xiaowei Wang, Shenzhen (CN); Nan Zhao, Shenzhen (CN)

(73) Assignee: Huawei Technologies Co., Ltd., Shenzhen (CN)

(21) Appl. No.: 13/754,515

(22) Filed: Jan. 30, 2013

(30) Foreign Application Priority Data
Feb. 28, 2012 (CN) 201210047332.6

(51) Int. Cl. H01L 23/498

(52) U.S. Cl. CPC H01L 23/49827
USPC 257/774

(57) ABSTRACT

A semiconductor device is provided in the present invention. The semiconductor device includes a silicon substrate, configured to bear a chip; a power management module arranged inside the silicon substrate, configured to convert a power supply voltage to an input voltage required by the chip; and an interconnecting system, configured to receive the power supply voltage, transmit the power supply voltage to the power management module, and transmit the input voltage to the chip. With the semiconductor device according to the embodiments of the present invention, the power supply voltage can be directly sent from the silicon substrate to the chip after being generated, thereby shortening the power supply link and reducing the power supply/ground noise.

### CROSS-REFERENCE TO RELATED APPLICATION

This application claims priority to Chinese Patent Application No. 201210047332.6, filed on Feb. 28, 2012, which is hereby incorporated by reference in its entirety.

### FIELD OF THE INVENTION

The present invention relates to a semiconductor device and a corresponding electronic apparatus.

### BACKGROUND OF THE INVENTION

As the chip technologies develop, a manner of chip layout on a PCB has emerged; that is, a layer of bearing plate is arranged on the PCB, and then chips are arranged on the bearing plate. Chips are electrically connected to a circuitry on the PCB through the through vias on the bearing plate. This makes a more reasonable use of the space on the PCB. In this case, a power management module arranged on the PCB can only supply power to the corresponding pins on the bearing plate through the through vias on the bearing plate.

However, as chips are increasingly highly integrated, different pins of a chip require diversified input voltage. As a result, the power management module on the PCB is required to provide various output pins. Diversified voltage output pins on the power management module cause complex problems such as power supply noises and electromagnetic interference/electromagnetic compatibility to other electric devices on the PCB, thereby significantly increasing the cost of the PCB.

Further, the output voltage of the power management module supplies power to the chips on the bearing plate through the through vias on the bearing plate, and the current generated during the running of the chips changes quickly; especially, the operating current of high-performance chips changes very drastically. However, the parasitic inductance of the power supply link packaged on the chip causes power supply/ground noise to the chip packaging system; if the power supply link is too long, the power supply/ground noise will be too high to meet the requirements of the high-performance chips.

### SUMMARY OF THE INVENTION

The present invention provides a semiconductor device, including: a silicon substrate, configured to bear a chip; a power management module arranged inside the silicon substrate, configured to convert a power supply voltage to an input voltage required by the chip; and an interconnecting system, configured to receive the power supply voltage, transmit the power supply voltage to the power management module, and transmit the input voltage to the chip.

The present invention further provides a corresponding electronic apparatus where the semiconductor device is adopted.

With the semiconductor device according to the embodiments of the present invention, the power supply voltage can be directly sent from the silicon substrate to the chip after being generated, thereby shortening the power supply link and reducing the power supply/ground noise.

### BRIEF DESCRIPTION OF THE DRAWINGS

To illustrate the technical solutions of the embodiments of the present invention more clearly, the following briefly describes the accompanying drawings required for describing the embodiments or the prior art. Apparently, the accompanying drawings in the following description merely show some embodiments of the present invention, and persons of ordinary skill in the art can derive other drawings from these drawings without creative efforts.

FIG. 1 is a schematic diagram of a semiconductor device according to an embodiment of the present invention; and

FIG. 2 is a schematic diagram of a semiconductor device according to another embodiment of the present invention.

### DETAILED DESCRIPTION OF THE EMBODIMENTS

The following clearly and completely describes the technical solutions according to the embodiments of the present invention with reference to the accompanying drawings in the embodiments of the present invention. Apparently, the embodiments in the following description are merely a part rather than all of the embodiments of the present invention. All other embodiments obtained by persons of ordinary skill in the art based on the embodiments of the present invention without creative efforts shall fall within the protection scope of the present invention.

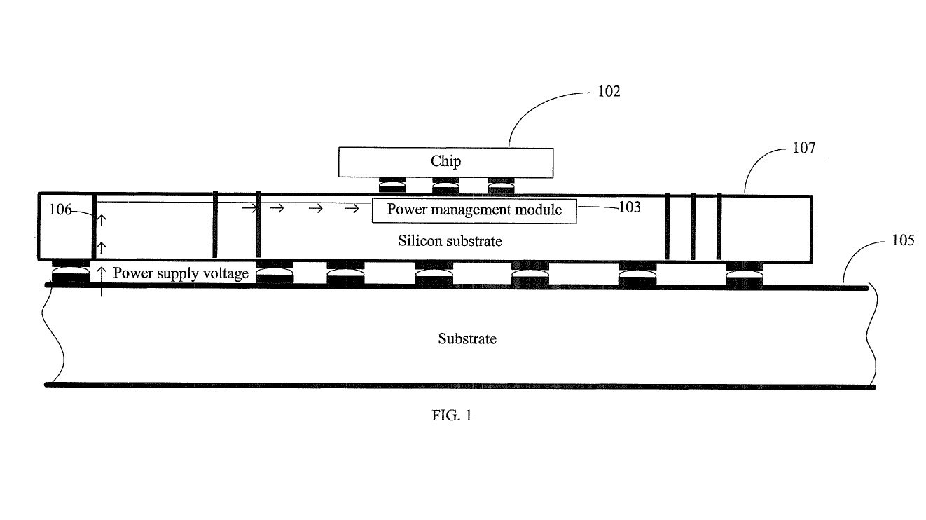

Refer to FIG. 1. FIG. 1 is a schematic diagram of an electronic apparatus which uses a semiconductor device according to an embodiment of the present invention. The semiconductor device according to this embodiment includes a silicon substrate 107 for bearing a chip 102, a power management module 103 arranged on the silicon substrate 107, and an interconnecting system arranged inside and on the surface of the silicon substrate 107. The power management module 103 is configured to receive a power supply voltage and convert the power supply voltage to an input voltage required by the chip 102. In this embodiment, the power management module 103 may be a power conversion circuit that is arranged on the surface of the silicon substrate 107 and converts the power supply voltage to the input voltage required by the chip 102. In other alternative embodiments, the power management module 103 may also be arranged at a certain circuit layer inside the silicon substrate 107 to provide the same function. The interconnecting system is configured to transmit the power supply voltage and the input voltage. The material composition of the silicon substrate comprises semiconductor silicon.

In practice, the silicon substrate 107 is arranged on a bearing plate 105. The bearing plate may be one of common circuit boards and is usually configured to connect signals and transmit power supply. In this embodiment, a power supply or a power supply interface for receiving external power supply is arranged on the bearing plate 105 to provide the power supply voltage for the silicon substrate 107. In other alternative embodiments, the bearing plate 105 may also be a substrate borne on another circuit board, and receive the power supply voltage from the circuit board, and transmit the power supply voltage to the silicon substrate 107.

The silicon substrate 107 can be fixed onto the bearing plate 105 using a tin solder, and can also be fixed onto the bearing plate 105 using a mechanical structure. When the silicon substrate 107 is fixed onto the bearing plate 105 using a tin solder, the power supply voltage on the bearing plate 105 can be transmitted to the silicon substrate 107 through a solder pad, the tin solder on the bearing plate 105, and a solder pad on the lower surface of the silicon substrate 107. Assuredly, the chip 102 can also be fixed to the silicon substrate 107 using a tin solder so that it is electrically connected to the silicon substrate 107 and receive the input voltage generated by the power management module 103 using a tin solder. As shown in FIG. 1, a solder pad is arranged on the lower surface of the chip 102 and is fixedly connected to a solder pad on the upper surface of the silicon substrate 107 so as to transmit electrical signals.

The interconnecting system is configured to transmit electric signals between the electric devices in the silicon substrate 107, and is configured to achieve the electric connection between the electric devices in the silicon substrate 107 and the outside; for example, the power supply voltage and the input voltage are transmitted between the bearing plate 105, the silicon substrate 107, and the chip 102 through the interconnecting system. Various functional modules with specific functions are arranged inside and on the surface of the silicon substrate 107, for example, power filtering and matching passive circuits, or the power management module 103 according to this embodiment. The interconnecting system according to this embodiment is configured to transmit signals or electricity for the functional modules. For example, the solder pads arranged on the upper and lower surfaces of the silicon substrate 107, electric paths inside and on the surface of the silicon substrate 107, and a voltage interface between the chip and the silicon substrate 107 all belong to the interconnecting system. The solder pad arranged on the lower surface of the silicon substrate 107 is configured to fix the silicon substrate 107 onto the bearing plate 105 using a tin solder and receive the power supply voltage from the bearing plate 105; and the solder pad arranged on the upper surface of the silicon substrate 107 is configured to fix the chip 102 using a tin solder and transmit the input voltage to the chip 102.

In this embodiment, the interconnecting system may further include a through silicon via (Through Silicon Via, TSV for short) 106. The through silicon via 106 is configured to transmit electric signals in the electric paths at different layers inside the silicon substrate 107. Specifically, in this embodiment, when the silicon substrate 107 obtains the power supply voltage from the bearing plate 105, the through silicon via 106 transmits the power supply voltage to the circuits connected to the corresponding interfaces of the power management module 103; and when the power management module 103 generates the input voltage, as shown in FIG. 1, the power management module 103 can directly transmit the power supply voltage to the chip 102 through the tin solder between the chip 102 and the silicon substrate 107. Assuredly, if the power management module 103 is not arranged on the surface of the silicon substrate 107, the input voltage can be transmitted to the voltage interface circuit between the silicon substrate 107 and the chip 102 through the through silicon via 106 or other voltage transmission circuits, so as to transmit the input voltage to the chip 102.

In this embodiment, a solder pad is arranged on the lower surface of the silicon substrate 107. Therefore, when the silicon substrate 107 is fixedly connected to the bearing plate 105 using a tin solder, the power supply voltage generated by the bearing plate 105 can be transmitted to the silicon substrate 107 using the tin solder. An electric path is arranged around one or more solder pads on the lower surface of the silicon substrate 107. When the power supply voltage is transmitted to the solder pad on the lower surface of the silicon substrate 107, the power supply voltage can be transmitted to the electric path in the corresponding through silicon via through the electric path around the solder pad, and then arrive at the electric path corresponding to the voltage input interface of the power management module 103 through the electric path in the through silicon via. After generating the power supply voltage, the power management module 103 transmits it to the chip 102 using a tin solder or a voltage interface.

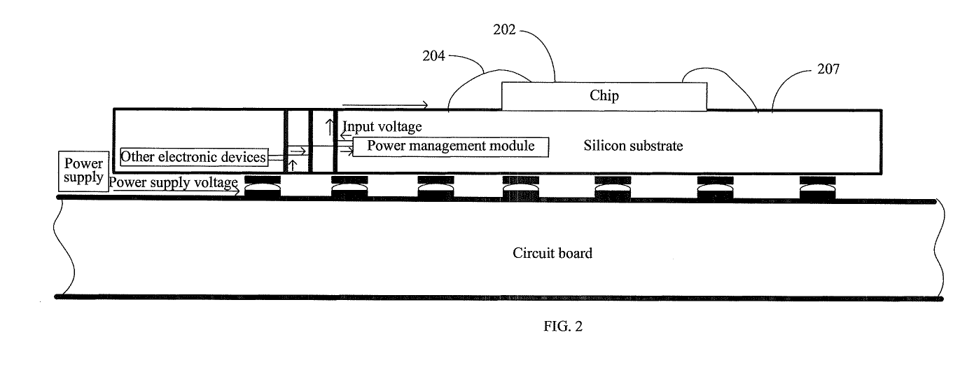

In practice, the electric signals between the chip, the silicon substrate, and the bearing plate are not necessarily transmitted using a solder pad or a tin solder. For example, as shown in FIG. 2, a chip 202 can be fixed onto a silicon substrate 207 using a tin solder or a mechanical structure; a jumper 204 is connected on the chip 202, and the jumper 204 is bonded onto the electric path of the silicon substrate 207 for receiving an input voltage. Similarly, the silicon substrate 207 can also receive a power supply voltage from a bearing plate 205 through a jumper. In other alternative embodiments, an external interface may be arranged on the silicon substrate. The external interface is connected to the power management module directly or through a through silicon via so as to receive the power supply voltage or transmit the input voltage. The bearing plate inputs the power supply voltage to the silicon substrate through a connecting piece matching the external interface, or the chip receives the input voltage from the silicon substrate through a connecting piece matching the external interface.

With the semiconductor device according to this embodiment, the power management module arranged in the silicon substrate may be possibly close to the chip to shorten the path for transmitting the power supply voltage, thereby significantly reducing the power supply/ground noise generated during the transmission of the power supply voltage.

The foregoing descriptions are merely exemplary embodiments of the present invention, but not intended to limit the protection scope of the present invention. Any variation or replacement made by persons skilled in the art without departing from the spirit of the present invention shall fall within the protection scope of the present invention. Therefore, the protection scope of the present invention shall be subject to the appended claims.

What is claimed is:

1. A semiconductor device, comprising:
a silicon substrate, configured to bear a chip;
a power management module arranged inside the silicon substrate, configured to convert a power supply voltage to an input voltage required by the chip; and
an interconnecting system, configured to receive the power supply voltage, transmit the power supply voltage to the power management module, and transmit the input voltage to the chip.

2. The semiconductor device according to claim 1, wherein the interconnecting system comprises a through silicon via, the through silicon via is arranged in the silicon substrate, and an electric path is arranged in the through silicon via to transmit the power supply voltage and the input voltage.

3. The semiconductor device according to claim 2, wherein the interconnecting system further comprises a solder pad arranged on the upper surface of the silicon substrate, the solder pad is configured to electrically connect to the chip, and the solder pad is electrically connected to the electric path in the through silicon via.

4. The semiconductor device according to claim 2, wherein the interconnecting system further comprises a solder pad arranged on the lower surface of the silicon substrate, the solder pad arranged on the lower surface of the silicon substrate is configured to receive the power supply voltage from a bearing plate, and the solder pad arranged on the lower surface of the silicon substrate is electrically connected to the through silicon via.

5. The semiconductor device according to claim 1, wherein the interconnecting system further comprises an external interface arranged on the silicon substrate, configured to receive the power supply voltage and transmit the power supply voltage to the power management module, or configured to transmit the input voltage generated by the power management module to the chip.

6. The semiconductor device according to claim 1, wherein the material composition of the silicon substrate comprises semiconductor silicon.

7. An electronic apparatus, comprising:
a chip;
a bearing plate, configured to provide a power supply voltage for the chip; and
a semiconductor device, comprising: a silicon substrate, configured to bear the chip; a power management module arranged inside the silicon substrate, configured to convert the power supply voltage to an input voltage required by the chip; and an interconnecting system, configured to receive the power supply voltage, transmit the power supply voltage to the power management module, and transmit the input voltage to the chip.

8. The electronic apparatus according to claim 7, wherein the interconnecting system comprises a through silicon via arranged on the silicon substrate, and an electric path is arranged in the through silicon via to transmit the power supply voltage and the input voltage.

9. The electronic apparatus according to claim 8, wherein the interconnecting system further comprises a solder pad arranged on the upper surface of the silicon substrate, the solder pad is configured to electrically connect to the chip, and the solder pad is electrically connected to the electric path in the through silicon via.

10. The electronic apparatus according to claim 8, wherein the interconnecting system further comprises a solder pad arranged on the lower surface of the silicon substrate, the solder pad arranged on the lower surface of the silicon substrate is configured to receive the power supply voltage from the bearing plate, and the solder pad arranged on the lower surface of the silicon substrate is electrically connected to the through silicon via.

11. The electronic apparatus according to claim 7, wherein the interconnecting system further comprises an external interface arranged on the silicon substrate, configured to receive the power supply voltage and transmit the power supply voltage to the power management module, or configured to transmit the input voltage generated by the power management module to the chip.

12. The electronic apparatus according to claim 7, wherein the material composition of the silicon substrate comprises semiconductor silicon.
